(19) United States
(12) Patent Application Publication
(10) Pub. No.: US 2024/0381574 A1
(43) Pub. Date: Nov. 14, 2024

(54) IMMERSION COOLING DEVICE

(71) Applicant: Fulian Precision Electronics (Tianjin) Co., LTD., Tianjin (CN)

(72) Inventors: TSUNG-LIN LIU, Neihu (TW); CHUN-WEI LIN, New Taipei (TW); YU-CHIA TING, Neihu (TW); CHIA-NAN PAI, Tu-Cheng (TW)

(21) Appl. No.: 18/221,435

(22) Filed: Jul. 13, 2023

(30) Foreign Application Priority Data
May 11, 2023 (CN) 202321129396.0

(51) Int. Cl. H05K 7/20

(52) U.S. Cl. CPC H05K 7/203; H05K 7/208

(57) ABSTRACT

An immersion cooling device includes a housing defining a receiving chamber, a working liquid received in the receiving chamber, a condenser received in the receiving chamber and located outside the working liquid, and a blocking member received in the receiving chamber. The blocking member includes a plurality of blocking bodies dispersed on a top surface of the working liquid.

### FIELD

The subject matter herein generally relates to heat dissipation, and more particularly, to an immersion cooling device.

### BACKGROUND

Electronic devices, such as servers, may generate heat during working. In order to dissipate the heat generated by the server, the server is placed into a housing receiving a coolant with a low boiling point. The coolant absorbs the heat generated by the server and vaporizes to dissipate the heat. The vaporized coolant then liquefies and condenses when it encounters the condenser. During a maintenance process, a cover plate of the housing is first opened to expose the server, and the server is then removed from the coolant. However, some of the vaporized coolant that is not fully condensed may escape out of the housing, resulting in a loss of the coolant. Therefore, there is room for improvement in the art.

### BRIEF DESCRIPTION OF THE DRAWINGS

Implementations of the present technology will now be described, by way of embodiment, with reference to the attached figures.

FIG. 1 is a perspective view of an immersion cooling device according to an embodiment of the present disclosure.

FIG. 2 is a perspective view of an immersion cooling device according to another embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and members have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and feat100ures of the present disclosure.

The term “comprising,” when utilized, means “including, but not necessarily limited to”; it specifically indicates open-ended inclusion or membership in the so-described combination, group, series, and the like.

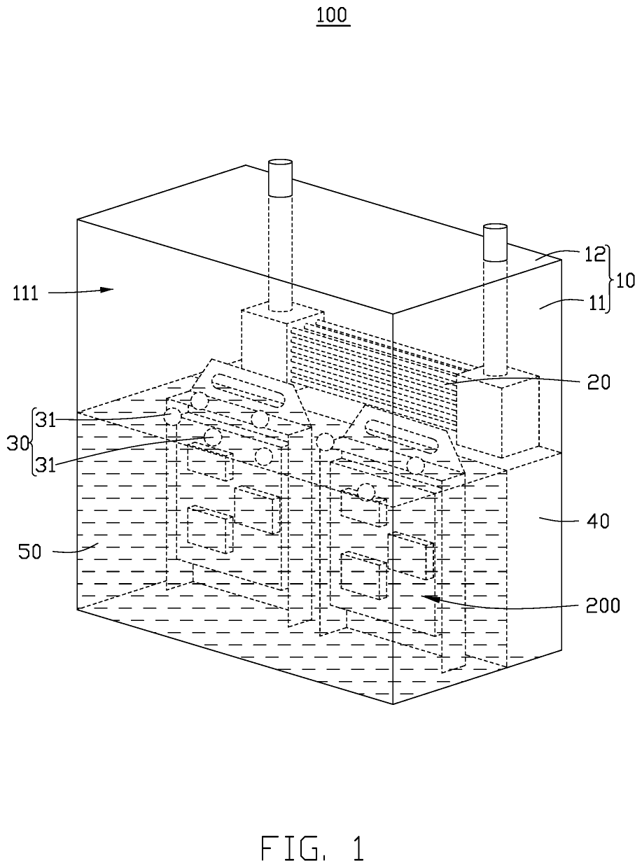

Referring to FIG. 1, an immersion cooling device 100 is provided according to an embodiment of the present disclosure. The immersion cooling device 100 can dissipate heat generated from at least one electronic device 200. Each electronic device 200 may be a server that generates heat during working.

The immersion cooling device 100 includes a housing 10, a condenser 20, and a blocking member 30. The housing 10 has a receiving chamber 111 for receiving a working liquid 50. Multiple electronic devices 200 may be immersed in the working liquid 50. The condenser 20 is received in the housing 10 and located outside the working liquid 50. When the working liquid 50 absorbs the heat generated by the electronic device 200 and vaporizes, the vapor reaches the condenser 20. The vapor directly condenses into liquid droplets when being in contact with the condenser 20, and then returns to the working liquid 50 again.

The blocking member 30 is received in the housing 10 and floated on a top surface of the working liquid 50. The blocking member 30 includes multiple blocking bodies 31 dispersed on the top surface of the working liquid 50. A density of each blocking body 31 is less than that of the working liquid 50. The blocking bodies 31 form a physical protective interface. When the receiving chamber 111 communicates with the outside environment (for example, when the housing 10 is opened by a user), the blocking bodies 31 can reduce the area of the top surface of the working liquid 50 that is exposed to the outside environment. Thus, the blocking bodies 31 can block and prevent the working liquid 50 from escaping out of the housing 10, thereby reducing the loss of the working liquid 50. During maintenance, the electronic device 200 can be directly removed from the working liquid 50 by moving the blocking bodies 31 toward a single side. Thus, the blocking bodies 31 do not affect the removal of the electronic device 200. Furthermore, when the immersion cooling device 100 is in use, the blocking bodies 31 are floated on the top surface of the working liquid 50. When the working liquid 50 absorbs the heat and reaches the boiling point, the bubbles generated by the working liquid 50 will push the blocking bodies 31 away, and the vapor of the working liquid 50 can move toward the condenser 20 without affecting the normal operation of the immersion cooling device 100.

With above configuration, the blocking bodies 31 can reduce the area of the working liquid 50 exposed to the outside environment, thereby reducing the amount of the working liquid 50 that escapes to the outside environment. Such structure is simple and easy to operate. The user can move the blocking bodies 31 toward a single side when he or she wants to observe the working status of the electronic device 200.

In at least one embodiment, each of the blocking bodies 31 is made of foam, so that the blocking bodies 31 can be floated on the working liquid 50. Each of the blocking bodies 31 may also be hollow inside, so that the blocking bodies 31 can be floated on the working liquid 50. Each of the blocking bodies 31 may be spherical or polyhedral.

In the embodiment, each of the blocking bodies 31 is a sunshade ball. The size of the sunshade ball is set according to actual needs. When viewing from a vertical direction (that is, a depth direction of the working liquid 50), the area of the blocking bodies 31 accounts for more than 90% of the area of the top surface of the working liquid 50, thereby reducing the area of the working liquid 50 that is exposed to the outside environment. The blocking bodies 31 may also completely cover the top surface of the working liquid 50.

In at least one embodiment, the working liquid 50 may be an insulating liquid, such as an insulating oil or fluoride.

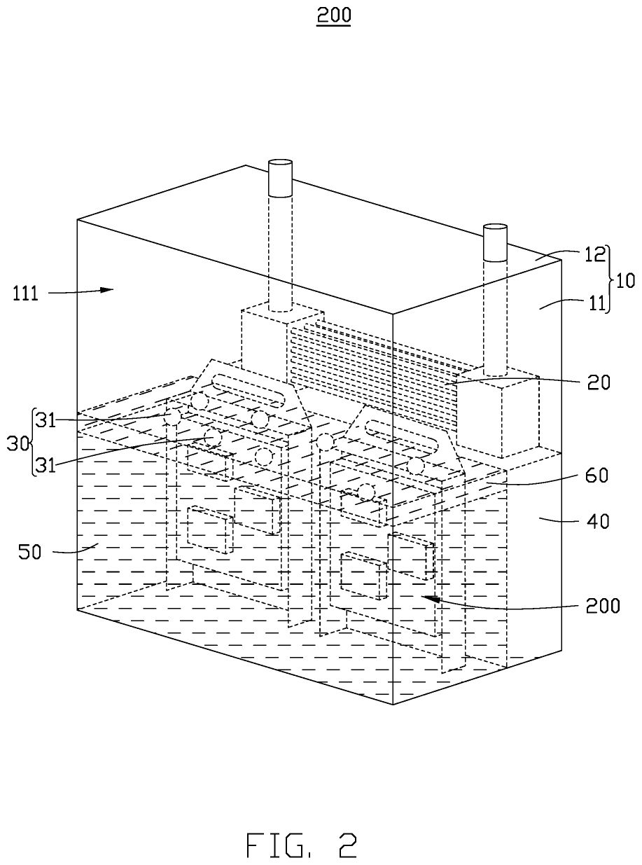

Referring to FIG. 2, an immersion cooling device 200 is also provided according to another embodiment of the present disclosure. Different from the immersion cooling device 100, a protective liquid 60 may also be provided on the working liquid 50. The density of the protective liquid 60 is less than that of the working liquid 50, and the protective liquid 60 is incompatible with the working liquid 50. The blocking bodies 31 are floated on the working liquid 50. The protective liquid 60 can further reduce the surface area of the working liquid 50 exposed from the outside environment. For example, the working liquid 50 is an insulating fluorinated electronic liquid with a density of 1.86 g/cm³, and the protective liquid 60 is a silicone oil with a density of 0.96 g/cm³.

Referring to FIGS. 1 and 2, in at least one embodiment, the housing 10 includes a body 11 and a cover 12 detachably connected to the body 11. The body 11 may be substantially rectangular with an opening at the top end, and the cover 12 covers the opening. One side of the cover 12 is rotatably connected to the body 11, and the other side of the cover 12 is detachably fixed to the body 11 such as by screwing or snap-fitting. A sealing member (not shown) may also be provided in the gap between the cover 12 and the inner wall of the body 11, which can improve the sealing performance between the body 11 and the cover 12 and reduce the amount of the working liquid 50 escaping out of the housing 10 when the immersion cooling device 100 or 200 is use.

In at least one embodiment, a support portion 40 is also received in the receiving chamber 111 of the housing 10. The condenser 20 is disposed on the support portion 40. The support portion 40 may be a bracket or a support plate. The support portion 40 protrudes from the inner wall or the bottom surface of the body 11.

The top surface of the support 40 is flush with the top surface of the working liquid 50, so that when the vapor directly condenses into liquid droplets when being in contact with the condenser 20, the liquid droplets can directly return to the working liquid 50. Furthermore, compared to the support portion 40 being higher than the working liquid 50, the present disclosure enables the vapor to quickly reach the condenser 20 and shortens the path of the vapor.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present embodiments to the full extent indicated by the plain meaning of the terms in which the appended claims are expressed.

What is claimed is:

1. An immersion cooling device comprising:
a housing defining a receiving chamber;
a working liquid received in the receiving chamber;
a condenser received in the receiving chamber and located outside the working liquid; and
a blocking member received in the receiving chamber, the blocking member comprising a plurality of blocking bodies dispersed on a top surface of the working liquid, a density of the plurality of blocking bodies being less than a density of the working liquid.

2. The immersion cooling device of claim 1, wherein the plurality of blocking bodies is made of foam.

3. The immersion cooling device of claim 1, wherein each of the plurality of blocking bodies is spherical or polyhedral.

4. The immersion cooling device of claim 3, wherein each of the plurality of blocking bodies is hollow.

5. The immersion cooling device of claim 1, wherein each of the plurality of blocking bodies is a sunshade ball.

6. The immersion cooling device of claim 1, wherein when viewing from a depth direction of the working liquid, a surface area of the plurality of blocking bodies accounts for more than 90% of the top surface of the working liquid.

7. The immersion cooling device of claim 1, further comprising a protective liquid disposed on the top surface of the working liquid, wherein a density of the protective liquid is less than the density of the working liquid, and the plurality of blocking bodies is dispersed on a top surface of the protective liquid.

8. The immersion cooling device of claim 7, wherein the working liquid is an insulating oil or insulating fluoride, and the protective liquid is silicone oil.

9. The immersion cooling device of claim 1, wherein the housing comprises a body and a cover detachably connected to the body, and the cover is configured to seal the receiving chamber.

10. The immersion cooling device of claim 1, further comprising a support portion received in the receiving chamber, wherein the condenser is located on the support portion.

11. The immersion cooling device of claim 10, wherein a top surface of the support portion is flush with the top surface of the working liquid.

12. An immersion cooling device comprising:
a housing defining a receiving chamber, the receiving chamber configured to receive a working liquid;
a condenser received in the receiving chamber and configured to located outside the working liquid; and
a blocking member received in the receiving chamber, the blocking member comprising a plurality of blocking bodies, the plurality of blocking bodies configured to be dispersed on a top surface of the working liquid, a density of the plurality of blocking bodies being less than a density of the working liquid.

13. The immersion cooling device of claim 12, wherein the plurality of blocking bodies is made of foam.

14. The immersion cooling device of claim 12, wherein each of the plurality of blocking bodies is spherical or polyhedral.

15. The immersion cooling device of claim 14, wherein each of the plurality of blocking bodies is hollow.

16. The immersion cooling device of claim 12, wherein each of the plurality of blocking bodies is a sunshade ball.

17. The immersion cooling device of claim 12, wherein a surface area of the plurality of blocking bodies accounts for more than 90% of the top surface of the working liquid.

18. The immersion cooling device of claim 12, wherein the housing comprises a body and a cover detachably connected to the body, and the cover is configured to seal the receiving chamber.

19. The immersion cooling device of claim 12, further comprising a support portion received in the receiving chamber, wherein the condenser is located on the support portion.
